(19) United States
(12) Patent Application Publication
(10) Pub. No.: US 2013/0292717 A1
(43) Pub. Date: Nov. 7, 2013

(54) LIGHT-EMITTING DEVICE WITH A TUNABLE LIGHT EMISSION SPECTRUM

(71) Applicant: Harry A. Seibel, II, Durham, NC (US)

(72) Inventor: Harry A. Seibel, II, Durham, NC (US)

(73) Assignee: Cree, Inc., Durham, NC (US)

(21) Appl. No.: 13/464,332

(22) Filed: May 4, 2012

(51) Int. Cl. H01L 33/50

(52) U.S. Cl. 257/89; 257/E33.061

(57) ABSTRACT

A light emitting device with a tunable light emission spectrum includes one or more blue LEDs in optical communication with n different red phosphor compositions. Each of the n different red phosphor compositions includes a different amount of strontium (Sr) and comprises light emission in a wavelength range from about 600 nm to about 675 nm. Each of the blue LEDs comprises light emission in a wavelength range from about 400 nm to about 475 nm. An m^{th} different red phosphor composition has a formula Ca_{1-x-y}SrₓEu_{y}AlSiN₃, with 0<x<1 and 0<y<1, and x=xₘ and 1≦m≦n. A light emission spectrum of the light emitting device comprises a blue spectral component from the one or more blue LEDs and a red spectral component from the n different red phosphor compositions, where the red spectral component comprises n overlapping light emission profiles each having a different peak emission wavelength λₘ.

### TECHNICAL FIELD

The present disclosure is related generally to light emitting devices and more particularly to light emitting devices comprising light emitting diodes and phosphors.

### BACKGROUND

Light emitting diodes (LEDs) are solid state devices that convert electric energy to light, and generally comprise one or more active layers of semiconductor material sandwiched between oppositely doped layers so as to define a p-n junction. When a bias is applied across the p-n junction, holes and electrons are injected into the active layer where they recombine to generate light in a process called injection electroluminescence. Light may be emitted from the active layer through all surfaces of the LED.

LEDs typically have a light emission spectrum or intensity distribution that is tightly centered about a peak emission wavelength (i.e., the wavelength corresponding to the maximum light intensity). The light emission spectrum of an LED may be further characterized in terms of the width of the intensity distribution measured at half the maximum light intensity (referred to as the full width at half maximum or “FWHM” width). An LED may be identified by its peak emission wavelength or, alternatively, by its “dominant” wavelength, which is the wavelength of monochromatic light that has the same apparent color as the light emitted from the LED as perceived by the human eye. Thus, the dominant wavelength differs from the peak wavelength in that the dominant wavelength takes into account the sensitivity of the human eye to different wavelengths of light.

As most LEDs are almost monochromatic light sources that appear to emit light having a single color, light emitting devices or lamps including multiple LEDs that can emit light of different colors have been employed to produce white light. In these devices, the different colors of light emitted by the individual LEDs combine to produce a desired intensity and/or color of white light. For example, by simultaneously energizing red, green and blue light emitting LEDs, the resulting combined light may appear white, or nearly white.

Besides combining individual LEDs to produce light emitting devices having a particular light emission spectrum, phosphorescent materials, or phosphors, may be used to control the color of light emitted from LEDs. A phosphor may absorb a portion of the light emitted from an LED at a given wavelength via the principle of injection electroluminescence and re-emit the light at different wavelength via the principle of photoluminescence. The conversion of light having a shorter wavelength (or higher frequency) to light having a longer wavelength (or lower frequency) may be referred to as down conversion. For example, a down-converting phosphor may be combined with a blue LED to convert some of the blue wavelengths to yellow wavelengths in order to generate white light.

Technological advances over the last decade or more have resulted in LEDs having a smaller footprint, increased emitting efficiency, and reduced cost. LEDs also have an increased operation lifetime compared to other emitters. For example, the operational lifetime of an LED can be over 50,000 hours, while the operational lifetime of an incandescent bulb is approximately 2,000 hours. LEDs can also be more robust than other lights sources and can consume less power. For these and other reasons, LEDs are becoming more popular and are being used in applications that have traditionally been the realm of incandescent, fluorescent, halogen and other emitters.

For example, high intensity discharge (e.g., metal halide, high pressure sodium) and fluorescent lamps have found application as “grow lights” in horticultural lighting systems for the purpose of promoting plant growth indoors. However, such lamps are inherently inefficiently as they emit broad spectrum radiation covering wavelengths of light that are not effective for promoting photosynthesis, and they have other disadvantages as well.

### BRIEF SUMMARY

A light emitting device having a tunable light emission spectrum has been developed. The light emitting device, which includes red phosphors of different compositions, may be engineered for applications where particular wavelengths of red light are needed (such as horticultural lighting systems) or where a broad spectrum of high intensity red light is desired. Used in conjunction with blue and optionally other light emitting diodes (LEDs) or phosphors, the red phosphor compositions of the present disclosure may be employed to produce non-white light or white light emitting devices for specific applications.

The light emitting device set forth herein includes one or more blue LEDs in optical communication with n different red phosphor compositions. Each of the n different red phosphor compositions includes a different amount of strontium (Sr) and comprises light emission in a wavelength range from about 600 nm to about 675 nm. Each of the blue LEDs comprises light emission in a wavelength range from about 400 nm to about 475 nm. An m^{th} different red phosphor composition has a formula Ca_{1-x-y}SrₓEu_{y}AlSiN₃, with 0<x<1 and 0<y<1, and x=xₘ and 1≦m≦n. A light emission spectrum of the light emitting device comprises a blue spectral component from the one or more blue LEDs and a red spectral component from the n different red phosphor compositions, where the red spectral component comprises n overlapping light emission profiles each having a different peak emission wavelength λₘ.

### BRIEF DESCRIPTION OF THE DRAWINGS

FIG. 1 is a schematic of a simulated light emission spectrum from four different red phosphor compositions and one or more blue LEDs;

FIG. 2 shows the absorbance spectra of chlorophyll a and chlorophyll b;

FIG. 3A is a cross-sectional schematic showing three blue LEDs disposed on a monolithic submount in optical communication with three different red phosphor compositions according to one embodiment, where the three blue LEDs and the three different red phosphor compositions are in one-to-one correspondence;

FIG. 3B is a cross-sectional schematic showing three blue LEDs disposed on a monolithic submount in optical communication with three different red phosphor compositions according to another embodiment, where the three blue LEDs and the three different red phosphor compositions are in one-to-one correspondence;

FIG. 4 shows a cross-sectional schematic of four blue LEDs contained in separate LED packages and disposed in optical communication with four different red phosphor compositions according to one embodiment, where the four blue LEDs and the four different red phosphor compositions are in one-to-one correspondence;

FIG. 5 shows a cross-sectional schematic of two blue LEDs disposed on a monolithic submount in optical communication with four different red phosphor compositions according to one embodiment, where each of the blue LEDs is in optical communication with two of the different red phosphor compositions; and

FIG. 6 shows a cross-sectional schematic of two blue LEDs contained in separate LED packages and disposed in optical communication with four different red phosphor compositions according to one embodiment, where each of the blue LEDs is in optical communication with two of the different red phosphor compositions.

### DETAILED DESCRIPTION

A light emitting device with a tunable light emission spectrum has been developed. The device is based on the combination of one or more blue LEDs and a plurality of different red phosphor compositions. Each red phosphor composition includes a different amount of strontium (Sr) and is represented by the formula Ca_{1-x-y}SrₓEu_{y}AlSiN₃, where 0<x<1 and 0<y<1. The light emitting device may be engineered for applications where a broad spectrum of red light is needed or where particular wavelengths of red light are desired. For example, by controlling the amount of Sr in the different red phosphor compositions, the light emitting device may be designed to emit wavelengths that promote photosynthesis, and the device can be employed as a growth light for horticultural lighting systems. The light emitting device may further include additional LEDs and/or phosphor compositions that produce additional spectral component(s) to enable the device to emit white light.

As used in the present disclosure, a “phosphor” or “phosphor composition” may refer to a material that absorbs light at one wavelength and re-emits the light at a different wavelength, where the re-emission includes visible light. The term phosphor may be used herein to refer to materials that are sometimes referred to as fluorescent and/or phosphorescent materials. The conversion of light having a shorter wavelength (or higher frequency) to light having a longer wavelength (or lower frequency) may be referred to as down conversion, and phosphors that can effect down-conversion may be referred to as down-converting phosphors.

Also as used herein, a “solid state light emitting device” or a “light emitting device” refers to a device including a light emitting diode (LED) or laser diode that is capable of emitting light.

The “peak emission” of a light emitting device, a light emitting diode (LED), or a phosphor composition is the maximum intensity of light emitted therefrom. The peak emission wavelength is the wavelength at which the maximum intensity of light is emitted. A light emitting device having an emission spectrum including two or more distinct spectral components in multiple wavelength ranges may have a peak emission within each wavelength range.

A first device or phosphor that is described as being “in optical communication with” a second device or phosphor is positioned such that light emitted from the first device reaches the second device.

The “color rendering index” (CRI) refers to a quantitative measure of the ability of a light source to reproduce the colors of objects in comparison with an ideal or natural light source. In contrast with correlated color temperature (CCT), which describes the apparent color of a light source, the CRI refers to the color appearance of objects that are illuminated by the light source. A commonly used CRI value is referred to as the general CRI and includes coefficients corresponding to eight medium saturated colors (R1-R8). What is known as the special CRI also includes coefficients corresponding to six highly saturated colors (R9-R14). Of these, R9 corresponds to a strong red color, which may affect a red-green contrast that may be beneficial in rendering colors.

It is understood that when an element such as a layer, region, or substrate is referred to as being “on” another element, it can be directly on the other element or intervening elements may also be present. Furthermore, relative terms such as “inner,” “outer,” “upper,” “above,” “over,” “overlying,” “beneath,” “below,” “top,” “bottom,” and similar terms, may be used herein to describe a relationship between elements. It is understood that these terms are intended to encompass orientations of the device that differ from those depicted in the figures.

Although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

The figures are intended as schematic illustrations. As such, the actual dimensions and shapes of the devices and components (e.g., layer thicknesses) can be different, and departures from the illustrations as a result of, for example, of manufacturing techniques and/or tolerances may be expected. Embodiments should not be construed as limited to the particular shapes of the regions illustrated herein but are to include deviations in shapes that result from, for example, manufacturing. A region illustrated or described as square or rectangular may have rounded or curved features due to normal manufacturing tolerances. Thus, the regions illustrated in the figures are schematic in nature and their shapes are not intended to illustrate the precise shape of a region of a device and are not intended to limit the scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

The light emitting device comprises one or more blue light emitting diodes (LEDs) in optical communication with n different red phosphor compositions. Each of the blue LEDs has light emission in a wavelength range from about 400 nm to about 475 nm when exposed to a suitable voltage, and each of the n different red phosphor compositions has light emission in a wavelength range from about 600 nm to about 675 nm when exposed to light from one of the one or more blue LEDs.

In particular, an m^{th} different red phosphor composition has the formula Ca_{1-x-y}SrₓEu_{y}AlSiN₃, where x=xₘ and 1≦m≦n, and where x (or xₘ) represents the mole fraction of Sr and the variable y represents the mole fraction of Eu (0<xₘ<1 and 0<y<1). Each of the different red phosphor compositions comprises a different amount of Sr. The amount of Eu, which serves as the activator or dopant for the (Ca,Sr)AISiN₃ crystal, may also be varied, as discussed further below.

A light emission spectrum of the light emitting device comprises a blue spectral component from the one or more blue LEDs and a red spectral component from the n different red phosphor compositions, where the red spectral component includes n overlapping light emission profiles each having a different peak emission wavelength λₘ. The amount of Sr in each of the different red phosphor compositions (i.e., the value of xₘ) strongly influences the peak emission wavelength λₘ of the respective light emission profile.

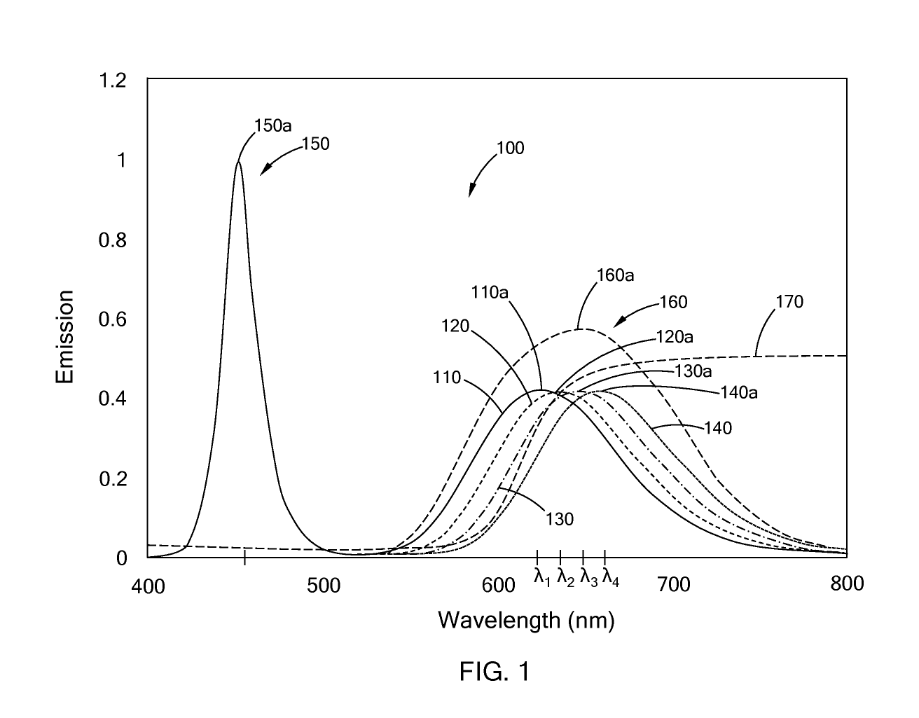

A light emission spectrum from an exemplary light emitting device is shown in FIG. 1. The non-white light emission spectrum 100 includes a blue spectral component 150 from the blue LED(s) and a red spectral component 160 from the red phosphor compositions. The blue spectral component 150 is produced by four LEDs of substantially identical compositions and has a maximum (i.e., peak emission) 150a in a wavelength range from about 400 nm to about 475 nm. The red spectral component 160 is defined by four overlapping light emission profiles 110, 120, 130, 140 from the red phosphor compositions, where each of the emission profiles has a maximum 110a, 120a, 130a, 140a at the peak emission wavelength λₘ.

As noted above, the different red phosphor compositions include different amounts of Sr, where an m^{th} red phosphor composition has the formula Ca_{1-x-y}SrₓEu_{y}AlSiN₃, where x=xₙ, and 1≦m≦n. The variable n represents the number of overlapping light emission profiles and also the number of different red phosphor compositions, which in this example is equal to 4 (n=4). Generally speaking, the value of n may range from 2 to 1,000. More practically, 2≦n≦100, or 2≦n≦20, or 2≦n≦10. The values of xₘ (and thus the amounts of Sr) for the red phosphor compositions may be chosen to achieve light emission profiles that have desired values of the peak emission wavelength λₘ.

Referring again to FIG. 1, the first red phosphor composition (corresponding to m=1 and x=x₁) generates a light emission profile 110 having a peak emission wavelength λ₁ at about 620 nm. The second red phosphor composition (corresponding to m=2 and x=x₂) generates a light emission profile 120 having a peak emission wavelength λ₂ at about 630 nm (λ₁+10 nm); the third red phosphor composition (corresponding to m=3 and x=x₃) generates a light emission profile 130 having a peak emission wavelength λ₃ at about 640 nm (λ₂+10 nm); and the fourth red phosphor composition (corresponding to m=4 and x=x₄) generates a light emission profile 140 having a peak emission wavelength λ₄ at about 650 nm (λ₃+10 nm). Exemplary values of x₁, x₂, x₃, and x₄ and y to achieve the peak emission wavelengths λₘ shown in FIG. 1 are provided in Table 1.

TABLE 1
Exemplary values of xₘ and y for given values of λₘ.

| m | λₘ (nm) | xₘ | y |
|---|---|---|---|
| 1 | 620 | .95 | 0.002 |
| 2 | 630 | .65 | 0.002 |
| 3 | 640 | .63 | 0.017 |
| 4 | 650 | .33 | 0.017 |

Generally speaking, the value of xₘ for each of the different red phosphor compositions, which represents the amount of Sr, is between 0 and 1, as stated above. In some embodiments, the value of xₘ may fall in the range of about 0.30 to about 0.95, or from about 0.40 to about 0.95, or from about 0.50 to about 0.90. Additionally, values of xₘ corresponding to different phosphor compositions may differ from adjacent values by an amount Δx of at least about 0.01, or at least about 0.05, or at least about 0.1. Generally, the amount Δx is no more than about 0.5, or no more than about 0.3, or no more than about 0.2. For example, the amount Δx may range from about 0.01 to about 0.5. The amount Δx may also range from about 0.1 to about 0.3.

The variable y, which represents the amount of the activator Eu, may be unchanged among the different red phosphor compositions. However, it is contemplated that y may also vary among the red phosphor compositions; that is, for the m^{th} red phosphor composition, y may be equal to yₘ, where 1≦m≦n as above. As described in U.S. patent application Ser. No. 13/361,276, “Methods of Determining and Making Red Nitride Compositions,” which was filed on Jan. 10, 2012, and is hereby incorporated by reference in its entirety, the amount of the activator may correlate to a particular CRI saturated color coefficient value. Specifically, it has been found that the Eu amount and the CRI R9 value are negatively correlated; i.e., as the Eu concentration increases, the CRI R9 value decreases. An exemplary CRI R9 curve 170 is shown in FIG. 1. In addition to effecting a change in the CRI R9 value of a light emitting device that includes the red phosphor composition, a change in the Eu concentration also may provide correlative changes in the relative brightness of the phosphor.

As a consequence of the different values of xₘ (and in some cases y) among the red phosphor compositions, values of the peak emission wavelength λₘ for the red phosphor compositions may differ from adjacent values thereof by an amount Δλ that ranges from about 1 nm to about 20 nm. The amount Δλ may also range from about 5 nm to about 10 nm.

Referring again to FIG. 1, the shape and size of the red spectral component 160 is determined by the combined light emission from the different red phosphor compositions. The light emission profiles 110, 120, 130, 140 from the different red phosphor compositions are overlapping emission profiles. In other words, at least a portion of the light emission profile from each red phosphor composition overlaps with the light emission profile from a different red phosphor composition. Consequently, the red spectral component 160 may have a higher intensity and cover a broader wavelength range than the emission profiles from any of the red phosphor compositions alone. In addition, the red spectral component 160 has a maximum 160a as shown in FIG. 1. In some cases, however, the overlapping light emission profiles from the different red phosphor compositions may define a red spectral component that has more than one distinct peak; in this situation, more than one maxima may be defined. By properly selecting the red phosphor compositions to be employed in the light emitting device, the red spectral component of the emission spectrum may be tailored for particular applications.

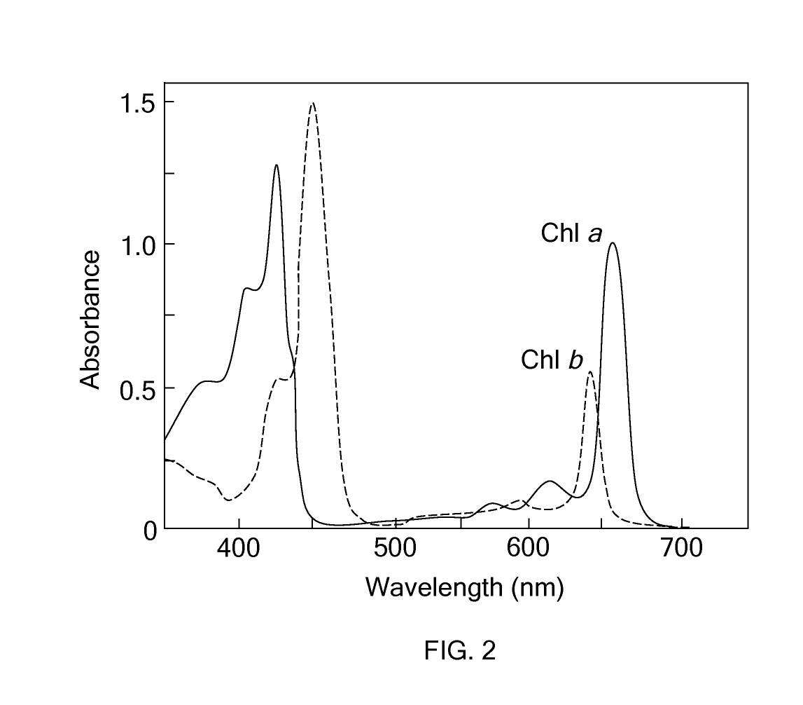

For example, the emission spectrum of the light emitting device may be tailored to promote photosynthesis. FIG. 2 shows the absorbance spectra of chlorophyll a and chlorophyll b, where absorbance peaks are present in the wavelength ranges of about 400-475 nm and about 600-675 nm. As shown in FIG. 2, peak absorption occurs at wavelengths of about 425 nm, 460 nm, 630 nm and 655 nm. Different red phosphor compositions having different Sr concentrations may be combined with one or more blue LEDs to produce a light emitting device having peak emission wavelengths that coincide with the absorbance spectra of chlorophyll a and chlorophyll b. The light emitting device may therefore efficiently stimulate photosynthesis.

Such a device may be based upon the combination of two different red phosphor compositions and two blue LEDs. For example, a first red phosphor composition used in the light emitting device may have x₁=0.45 and y=0.015, and a second red phosphor composition may have x₂=0.85 and y=0.015. The peak emission wavelength λ₁ of the first red phosphor is about 655 nm and the peak emission wavelength λ₂ of the second red phosphor is about 630 nm. The two blue LEDs may be put into optical communication with the first and second red phosphor compositions by employing one of the configurations described below, which are applicable to any light emitting device that may be fabricated using a plurality of red phosphor compositions and one or more blue LEDs.

As indicated, the light emitting device may include a single blue LED in combination with two or more different phosphor compositions; however, it may be advantageous to employ a plurality of the blue LEDs. Any configuration of LEDs known in the art can be employed. For example, each of the blue LEDs may be contained within a separate LED package and configured for optical communication with one or more of the different red phosphor compositions. A plurality of the LED packages may then be assembled to form the light emitting device. Alternatively, the plurality of blue LEDs may be provided on a monolithic submount where each of the blue LEDs is in optical communication with one or more of the different red phosphor compositions. The blue LEDs may further be arranged in an ordered (i.e., periodic) or a disordered (i.e., random) array.

Optical communication between the red phosphor compositions and the blue LEDs may be achieved by, for example, direct coating of one or more of the red phosphors onto the blue LEDs and/or by direct coating of one or more of the red phosphors onto one or more lenses overlying (or adjacent to, depending on the orientation) the blue LEDs. The red phosphors may be mixed with a binder for the coating process. At least two different red phosphor compositions are employed, and they may be mixed together or they may be physically separated from each other.

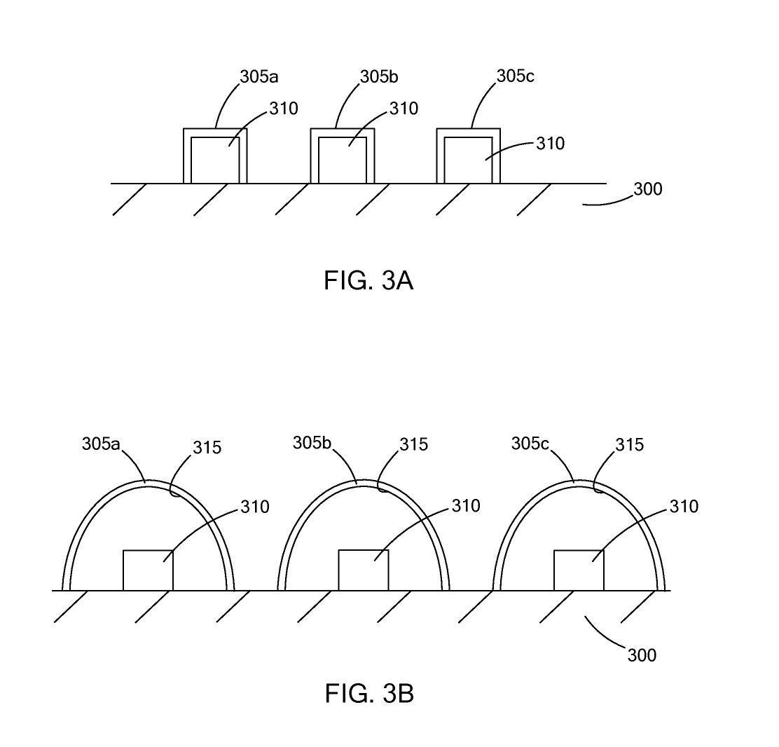

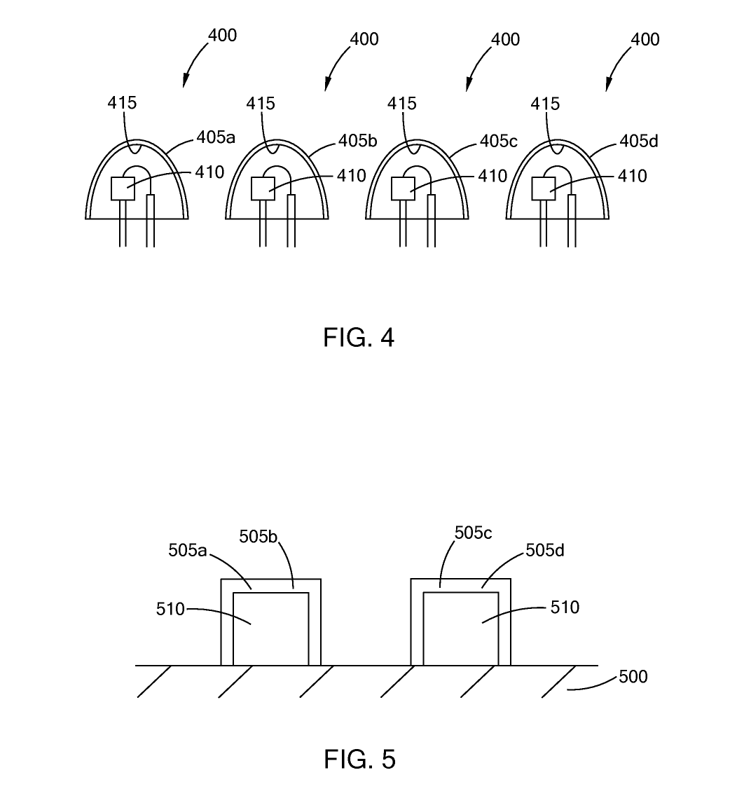

Each of the blue LEDs is in optical communication with at least one of the red phosphor compositions. It may be advantageous for each of the blue LEDs to be in optical communication with only one of the red phosphor compositions. According to this embodiment, there may be a one-to-one correspondence between the blue LEDs and the different red phosphor compositions, and the different red phosphor compositions may be physically separated from each other. Examples of this embodiment of the light emitting device are provided in FIGS. 3A-3B and 4.

A plurality of blue LEDs in optical communication with (and having a one-to-one correspondence with) a plurality of different red phosphors may be positioned as shown in FIGS. 3A and 3B, where three blue LEDs 310 are disposed on a monolithic submount 300 and the different red phosphor compositions 305a, 305b, 305c are coated directly thereon (FIG. 3A) or are deposited onto lenses 315 overlying the blue LEDs (FIG. 3B).

According to another embodiment, a plurality of blue LEDs 410 may be contained in separate LED packages 400, and the different red phosphor compositions 405a, 405b, 405c, 405d may be coated directly onto overlying lenses 415 that are part of the LED packages 400, thereby effecting optical communication and a one-to-one correspondence between the LEDs 410 and the phosphor compositions 405a, 405b, 405c, 405d.

As an alternative to having one-to-one correspondence between the blue LEDs and the red phosphor compositions, one or more of the blue LEDs may be in optical communication with more than one of the different phosphor compositions.

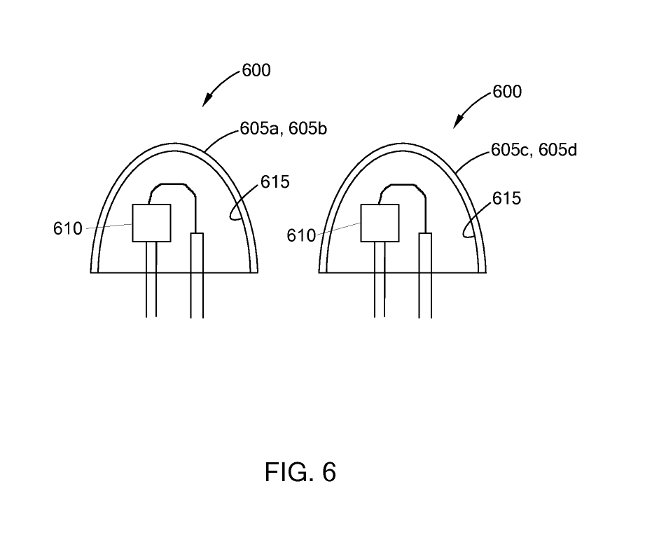

According to this embodiment, two or more of the different red phosphor compositions may be mixed together and directly coated on or otherwise disposed over one of the blue LEDs so as to be in optical communication with the blue LED. For example, referring to FIG. 5, 1^{st} and 2^{nd} phosphor compositions 505a, 505b having different amounts of Sr corresponding to x=x₁ and x=x₂, respectively, may be mixed together and directly coated on a first blue LED 510, which is shown disposed on a monolithic submount 500, while 3^{rd} and 4^{th} phosphor compositions 505c, 505d corresponding to x=x₃ and x=x₄ may be mixed together and directly coated on a second blue LED 510, which is also disposed on the submount. As indicated above, each blue LED may alternatively be contained in a separate LED package 600, in which case the 1^{st} and 2^{nd} phosphor compositions 605a, 605b may be directly coated onto an overlying lens 615 that is part of a first LED package 600 containing the first blue LED 610, and the 3^{rd} and 4^{th} phosphor compositions 605c, 605d may be directly coated onto an overlying lens 615 that is part of a second LED package 600 containing the second blue LED 610, as shown in FIG. 6.

For the sake of illustration, each of the first and second blue LEDs in the examples of FIGS. 5 and 6 is in optical communication with two of the different red phosphor compositions, but other combinations are also possible. For example, one or more of the blue LEDs may be in optical communication with two or more of the red phosphor compositions, with three or more of the red phosphor compositions, with four or more of the red phosphor compositions, or with all of the n different red phosphor compositions. In each of these cases, some or all of the n different phosphor compositions may be mixed together during processing of the light emitting device.

The exemplary light emitting devices described above, which combine one or more blue LEDs with the n different red phosphor compositions, may emit non-white light. The light emitting devices may include additional LEDs and/or phosphor compositions that produce additional spectral component(s) to enable the device to emit white light. For example, the light emitting device may further comprise a green LED comprising light emission in a wavelength range from about 500 nm to about 570 nm to provide a green spectral component of the light emission spectrum.

The simulated emission spectrum of FIG. 1 is derived from a light emitting device that includes four blue LEDs in optical communication with (and in one-to-one correspondence with) four different red phosphor compositions. In this example, all of the blue LEDs may have the same composition and peak emission wavelength. However, it is contemplated that the blue light emission profile may also be tuned by using blue LEDs of differing compositions that have different peak emission wavelengths.

The blue LEDs used herein are typically based on gallium nitride/silicon carbide technology, such as EZ1400 Gen II LEDs manufactured and sold by Cree, Inc. of Durham, N.C. Such LEDs and/or lasers may be configured to operate such that light emission occurs through the substrate in a so-called “flip chip” orientation. The solid state light emitting devices may be vertical devices with a cathode contact on one side of the chip and an anode contact on an opposite side of the chip and devices in which both contacts are on the same side of the chip.

The red phosphor compositions described herein may be made according to the method set forth in U.S. Patent Application Publication 2010/0123104, entitled “Phosphor Composition,” which is hereby incorporated by reference in its entirety.

The method may include forming a mixture comprising: a cation from the group consisting of calcium, strontium, lithium, sodium, potassium, rubidium, cesium, magnesium, barium, scandium, yttrium, lanthanum, gadolinium, and lutetium; with a cation from the group consisting of aluminum, silicon, boron, gallium, carbon, germanium, and phosphorus; with an anion selected from the group consisting of nitrogen, sulfur, chlorine, bromine, and iodine; and with an activator selected from the group of europium (II), cerium (III), ytterbium (II), samarium (II) and manganese (II). For example, nitrides of calcium, strontium, aluminum and silicon (e.g., Ca₃N₂, Sr₂N, AlN and Si₃N₄) may be mixed with a europium source composition such as europium fluoride to form the mixture. The mixture is heated in the presence of a forming gas at or near atmospheric pressure to form the phosphor composition, which may include silicon aluminum oxynitride in addition to Ca_{1-x-y}SrₓEu_{y}AlSiN₃. The forming gas may include nitrogen, and it may further include hydrogen. For example, the forming gas may be a mixture of nitrogen and hydrogen, where the hydrogen is present at a concentration of about 10% or less.

It should be noted that the phrase “composition containing a cation,” as used in the preceding paragraph, refers to a composition (e.g., a precursor) that may produce, under the reaction conditions, the element as a cation in the resulting phosphor composition. The element does not necessarily need to be present as a cation in the source material. In addition, the phrase “europium source composition” refers to a composition (e.g., europium fluoride) that will produce europium as the activator cation in the crystal lattice of the phosphor under the reaction conditions set forth herein.

The heating of the mixture in the presence of the forming gas may be carried out in the substantial absence of water and oxygen and is typically done in a refractory metal crucible. The temperature of the heating is sufficient to produce the red phosphor composition but less than the temperature at which the precursor compositions or the phosphor would decompose or react with the crucible. Most typically, the heating is carried out at a temperature of between about 1500° C. and 1800° C., although higher temperatures, e.g., between about 1800° C. and 2000° C., may also be suitable.

To vary the amount of strontium in the different red phosphor compositions (i.e., the value of x), different proportions of the strontium precursor (e.g., strontium nitride Sr₂N) may be employed in the respective mixtures. For example, different levels of Sr may be incorporated in the red phosphor compositions through typical solid state means, where an additional amount of a Sr-containing precursor (e.g., Sr₂N, SrCO₃, Sr₂O₃, etc.) is added and less of a Ca-containing precursor (e.g., Ca₃N₂, CaCl₂, CaCO₃, CaO) is added. In other words, additional Sr is exchanged for a Ca deficiency.

Although the present invention has been described in considerable detail with reference to certain embodiments thereof, other embodiments are possible without departing from the present invention. The spirit and scope of the appended claims should not be limited, therefore, to the description of the preferred embodiments contained herein. All embodiments that come within the meaning of the claims, either literally or by equivalence, are intended to be embraced therein.

Furthermore, the advantages described above are not necessarily the only advantages of the invention, and it is not necessarily expected that all of the described advantages will be achieved with every embodiment of the invention.

1. A light emitting device with a tunable light emission spectrum, the light emitting device comprising:
one or more blue light emitting diodes (LED) in optical communication with n different red phosphor compositions, each of the n different red phosphor compositions including a different amount of strontium (Sr) and comprising light emission in a wavelength range from about 600 nm to about 675 nm, the one or more blue LEDs comprising light emission in a wavelength range from about 400 nm to about 475 nm,
wherein an m^{th} different red phosphor composition has a formula Ca_{1-x-y}SrₓEu_{y}AlSiN₃, with 0<x<1 and 0<y<1, and x=xₘ and 1≦m≦n, and
wherein a light emission spectrum of the light emitting device comprises a blue spectral component from the one or more blue LEDs and a red spectral component from the n different red phosphor compositions, the red spectral component comprising n overlapping light emission profiles each having a different peak emission wavelength λₘ.

2. The light emitting device of claim 1 further comprising a plurality of the blue LEDs.

3. The light emitting device of claim 2 wherein each of the blue LEDs is in optical communication with only one of the n different red phosphor compositions.

4. The light emitting device of claim 2 wherein each of the blue LEDs is in optical communication with at least one of the n different red phosphor compositions.

5. The light emitting device of claim 2 wherein each of the blue LEDs is in optical communication with all of the n different red phosphor compositions.

6. The light emitting device of claim 2 further comprising a monolithic submount supporting the blue LEDs.

7. The light emitting device of claim 2 further comprising a plurality of LED packages, each of the blue LEDs being contained within one of the LED packages.

8. The light emitting device of claim 1 wherein at least a portion of the n different red phosphor compositions are mixed together.

9. The light emitting device of claim 1 wherein an entirety of the n different red phosphor compositions are mixed together.

10. The light emitting device of claim 1 wherein the n different red phosphor compositions are physically separated.

11. The light emitting device of claim 1 wherein xₘ ranges from about 0.40 to about 0.90.

12. The light emitting device of claim 1 wherein values of xₘ differ from adjacent values thereof by an amount Δx ranging from about 0.01 to about 0.5.

13. The light emitting device of claim 12 wherein the amount Δx ranges from about 0.05 to about 0.2.

14. The light emitting device of claim 1 wherein values of the peak emission wavelength λₘ differ from adjacent values thereof by an amount Δλ ranging from about 1 nm to about 20 nm.

15. The light emitting device of claim 14 wherein the amount Δλ ranges from about 5 nm to about 10 nm.

16. The light emitting device of claim 1 wherein y ranges from about 0.005 to about 0.02.

17. The light emitting device of claim 16 wherein y is about 0.015.

18. The light emitting device of claim 1 wherein y=yₘ each of the different red phosphor compositions comprising a different amount of Eu.

19. The light emitting device of claim 1 wherein the light emission spectrum is optimized for promoting photosynthesis.

20. The light emitting device of claim 19 wherein n=2, x₁=0.45, and x₂=0.85.

21. The light emitting device of claim 1 further comprising a green LED comprising light emission in a wavelength range from about 510 nm to about 580 nm, the light emission spectrum thereby further comprising a green spectral component.
